(19) United States
(12) Patent Application Publication
(10) Pub. No.: US 2022/0190163 A1
(43) Pub. Date: Jun. 16, 2022

(54) SEMICONDUCTOR DEVICE

(71) Applicant: Japan Display Inc., Tokyo (JP)

(72) Inventors: Takeshi SAKAI, Tokyo (JP); Masashi TSUBUKU, Tokyo (JP)

(73) Assignee: Japan Display Inc., Tokyo (JP)

(21) Appl. No.: 17/549,867

(22) Filed: Dec. 14, 2021

(30) Foreign Application Priority Data
Dec. 16, 2020 (JP) 2020-208511

(51) Int. Cl. H01L 29/786

(52) U.S. Cl. CPC H01L 29/7869; H01L 29/78651

(57) ABSTRACT

According to one embodiment, a semiconductor device includes a first insulating layer, an oxide semiconductor disposed on the first insulating layer, a second insulating layer which covers the oxide semiconductor and a gate electrode disposed on the second insulating layer and overlapping the oxide semiconductor. The oxide semiconductor includes a first region overlapping the gate electrode and a second region not overlapping the gate electrode. The first insulating layer, the second region and the second insulating layer contain impurities of a same type. The impurities contained in a region directly below the second region in the first insulating layer are more than the impurities contained in the second region.

### CROSS-REFERENCE TO BELATED APPLICATIONS

This application is based upon and claims the benefit of priority from Japanese Patent Application No. 2020-208511, filed Dec. 16, 2020, the entire contents of which are incorporated herein by reference.

### FIELD

Embodiments described herein relate generally to a semiconductor device.

### BACKGROUND

For example, in the field of the liquid crystal display, such a technology is proposed that a transistor comprising an oxide semiconductor is provided in a pixel circuit in a display area and a transistor comprising a silicon semiconductor is provided in a drive circuit in a peripheral area.

### BRIEF DESCRIPTION OF THE DRAWINGS

FIG. 1 is a cross-sectional view showing a configuration example of a semiconductor device 1 according to an embodiment.

FIG. 2 is a cross-sectional view illustrating a method of manufacturing a transistor TR2.

FIG. 3 is a cross-sectional view illustrating the method of manufacturing the transistor TR2.

FIG. 4 is a cross-sectional view illustrating the method of manufacturing the transistor TR2.

FIG. 5 is a diagram showing results of analysis of the first example.

FIG. 6 is a diagram showing results of analysis of the second example.

### DETATLED DESCRIPTION

In general, according to one embodiment, a semiconductor device comprises an insulating substrate, a first insulating layer disposed above the insulating substrate, an oxide semiconductor disposed on the first insulating layer, a second insulating layer which covers the oxide semiconductor and a gate electrode disposed on the second insulating layer and overlapping the oxide semiconductor, end the oxide semiconductor includes a first region overlapping the gate electrode and a second region not overlapping the gate electrode, the first insulating layer, the second region and the second insulating layer contain impurities of a same type, and the impurities contained in a region directly below the second region in the first insulating layer are more than the impurities contained in the second region.

Embodiments will be described hereinafter with reference to the accompanying drawings.

Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof may be omitted unless otherwise necessary.

Note that, in order to make the descriptions more easily understandable, some of the drawings illustrate an X axis, a Y axis and a Z axis orthogonal to each other. A direction along the X axis is referred to as an X direction or a first direction, a direction along the Y axis is referred to as a Y direction or a second direction and direction along the Z axis is referred to as a Z direction or a third direction. A plane defined by the X axis and the Y axis is referred to as an X-Y plane, and viewing towards the X-Y plane is referred to as planar view.

A semiconductor device 1 of this embodiment is applicable to various display devices such as liquid crystal displays, organic electroluminescent displays, electrophoretic displays, and LED displays, as well as various sensors such as capacitive sensors and optical sensors, and other electronic devices.

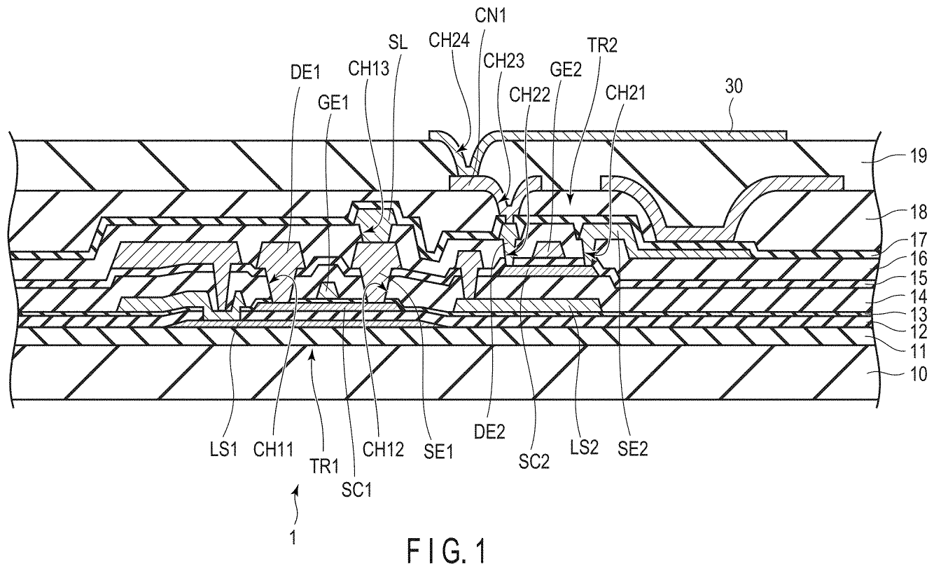

FIG. 1 is a cross-sectional view of a configuration example of the semiconductor device 1 of this embodiment.

The semiconductor device 1 comprises a base 10, insulating layers 11 to 19, transistors TR1 and TR2, and an element electrode 30.

The transistor TR1 comprises a semiconductor SC1, a gate electrode (first gate electrode) GE1, a source electrode (first source electrode) SE1, and a drain electrode (first drain electrode) DE1. The semiconductor SC1 is, for example, a polycrystalline silicon semiconductor, but it may be some other silicon semiconductor. The gate electrode GE1 is an electrode electrically connected to a respective gate line. The source electrode SE1 is an electrode electrically connected to a respective source line SL.

The transistor TR2 comprises a semiconductor SC2, a gate electrode (second gate electrode) GE2, a source electrode (second source electrode) SE2, and a drain electrode (second drain electrode) DE2. The semiconductor SC2 is, for example, an oxide semiconductor. The gate electrode GE2 is an electrode electrically connected to a respective gate line. The source electrode SE2 is an electrode electrically connected to a respective source line, power line or the like. The drain electrode DE2 is an electrode electrically connected to the element electrode 30.

The base 10 is an insulating substrate formed of an insulating material such as glass and resin film. The insulating layer 11 is disposed on the base 10.

The light-shielding layer LS1 is provided for the transistor TR1, and is disposed on the insulating layer 11 and covered by the insulating layer 12. The light-shielding layer LS1 is, for example, a metal layer. The semiconductor SC1 is located directly above the light-shielding layer LS1, is disposed on the insulating layer 12 and covered by the insulating layer 13.

The gate electrode GE1 is located directly above the semiconductor SC1, is disposed on the insulating layer 13 and covered by the insulating layer 14. The gate electrode GE1 is at the same potential as that of the light-shielding layer LS1, for example.

The source electrode SE1 and the drain electrode DE1 are located on the insulating layer 15 and covered by the insulating layer 16. The source electrode SE1 and the drain electrode DE1 are in contact with the semiconductor SC1 via contact holes CH11 and CH12, respectively, which penetrate the insulating layers 13 to 15.

The source line SL is disposed on the insulating layer 16 and is covered by the insulating layer 17. The source line SL is in contact with the source electrode SE1 via a contact hole CH13 that penetrates the insulating layer 16.

The light-shielding layer LS2 is provided for the transistor TR2, is disposed on the insulating layer 13 and covered by the insulating layer 14. The gate electrode GE1 and the light-shielding layer LS2 are metal layers located in the same layer and formed of the same material. The semiconductor SC2 is located directly above the light-shielding layer LS2, is disposed on the insulating layer 14 and covered by the insulating layer 15.

The gate electrode GE2 is located directly above the semiconductor SC2, disposed on the insulating layer 15 and covered by the insulating layer 16. The gate electrode GE2 is at the same potential as that of the light-shielding layer LS2, for example. The gate electrode GE2, the source electrode SE1 and the drain electrode DE1 are metal layers located in the same layer and formed of the same material.

The source electrode SE2 and the drain electrode DE2 are located on the insulating layer 16 and are covered by the insulating layer 17. The source electrodes SE2 and the drain electrodes DE2 are in contact with the semiconductor SC2 via contact holes CH21 and CH22, respectively, that penetrate the insulating layers 15 and 16. The source electrode SE2, the drain electrode DE2 and the source line SL are metal layers located in the same layer and formed of the same material.

A connection electrode CN1 is located on the insulating layer 18 and is covered by the insulating layer 19. The connection electrode CN1 is in contact with the drain electrode DE2 via a contact hole CH23 that penetrates the insulating layers 17 and 18. The connection electrode CN1 is a transparent electrode formed of, for example, a transparent conductive material such as indium tin oxide (ITO) or indium zinc oxide (IZO), but it may as well be a metal layer.

The element electrode 30 is disposed on the insulating layer 19 and is in contact with the connection electrode CN1 via a contact hole CH24 that penetrates the insulating layer 19. The element electrode 30 constitutes a pixel electrode, a bottom electrode, an anode or a cathode of various electronic devices. The element electrode 30 is a transparent electrode formed of, for example, a transparent conductive material such as ITO or IZO. Note that the element electrode 30 may as well be a metal electrode formed of a metal material such as silver or aluminum. Further, the element electrode 30 may be of a stacked body of a transparent electrode and a metal electrode. For example, the element electrode 30 may be configured as a stacked body in which a transparent electrode, a metal electrode and a transparent electrode are stacked in this order, or may be configured as a stacked body consisting of three or more layers.

The insulating layers 11 to 17 are transparent inorganic insulating layers formed, for example, of silicon nitride (SiN), silicon oxide (SiO) and the like. Note that each of the insulating layers 11 to 17 may be a monolayer formed of a single insulating material or may be a stacked body formed by multiple insulating materials.

The insulating layers 18 and 19 are transparent organic insulating layers formed of polyimide or the like.

Next, an example of the method of manufacturing the transistor TR2 shown in FIG. 1 will be described.

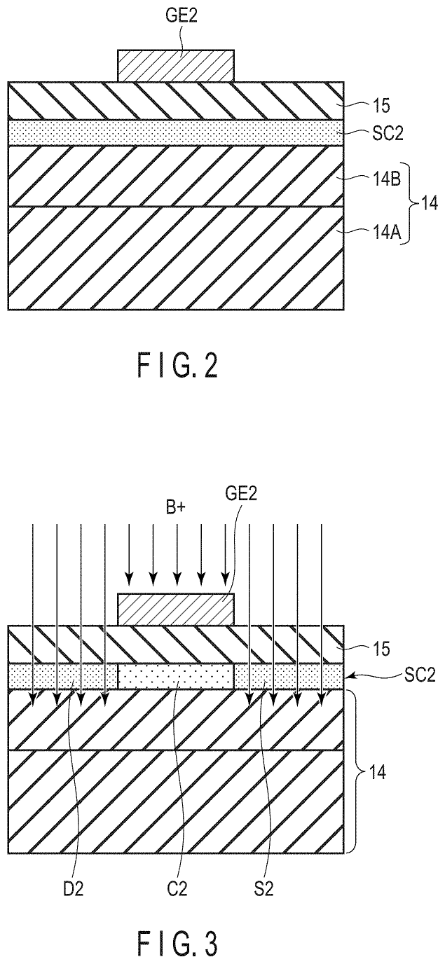

First, as shown in FIG. 2, after forming the insulating layer 14, an oxide semiconductor film is formed on the insulating layer 14, and the oxide semiconductor film is patterned into an island-shaped semiconductor (oxide semiconductor) SC2. The insulating layer 14 is, for example, a stacked body of a thin film 14A formed by depositing silicon nitride and a thin film 14B formed by depositing silicon oxide. The semiconductor SC2 is in contact with the thin film 14B.

Then, silicon oxide is deposited on the insulating layer 14 and the semiconductor SC2 to form the insulating layer 15. Thus, the semiconductor SC2 is located between the thin film (first insulating layer) 14B which is silicon oxide, and the insulating layer (second insulating layer) 15 which is silicon oxide.

After that, on the insulating layer 15, a metal film is formed and then patterned to form a gate electrode GE2 overlapping the semiconductor SC2. The gate electrode GE2 is formed, for example, by a titanium-based metal layer, an aluminum-based moral layer, and a stacked boy of titanium-based metal layers, or a molybdenum-tungsten alloy.

Next, as shown in FIG. 3, ion implantation is carried out on the semiconductor SC2 using the gate electrode GE2 as a mask. For example, boron (B) is doped into the semiconductor SC2 as an impurity by ion implantation. Note that the impurity to be doped is not limited to boron.

Thus, a channel region (first region) C2 where substantially no impurities are doped is formed in the semiconductor SC2 as a region overlapping the gate electrode GE2. At the same time, a source region (second region) S2 and a drain region (second region) D2, which impurities are doped, are formed as regions not overlapping the gate electrode GE2.

Note that between the channel region C2 and the source region S2, a region with an impurity concentration higher than that of the channel region C2 and an impurity concentration lower than that of the source region S2 may be formed. Similarly, between the channel region C2 and the drain region D2, a region with an impurity concentration higher than that of the channel region C2 and lower than that of the drain region D2 may be formed.

Further, by the ion implantation, impurities (e.g., boron) of a similar type to those of the source region S2 and the drain region D2 are doped into the gate electrode GE2, to a region of the insulating layer 15, which do not overlap the gate electrode GE2, a region of the insulating layer 14, which is directly under the source region S2, and a region of the insulating layer 14, which is directly under the drain region D2.

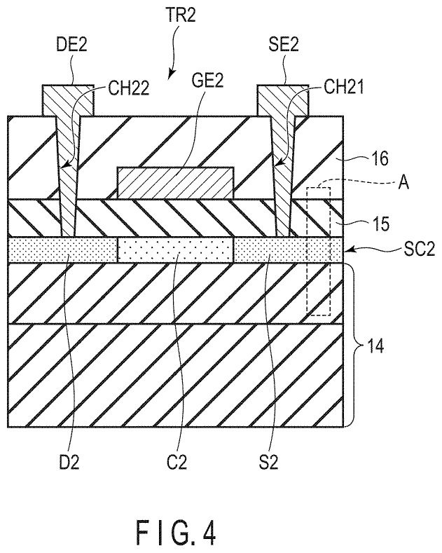

Subsequently, as shown in FIG. 4, the insulating layer 16 is formed, the contact holes CH21 and CH22 are formed to penetrate the insulating layers 15 and 16, and the source electrode SE2 and the drain electrode DE2 are formed. Thus, the semiconductor device 1 comprising the transistor TR2 is manufactured.

Next, impurities contained in the area A enclosed by the dotted line in the cross-sectional view of FIG. 4 were detected by secondary ion mass spectrometry, and the distribution of impurities due to differences in acceleration energy were compared. The region A corresponds to a region of a zone covering the region directly above the source region S2 in the insulating layer 14, the source region 52 in the semiconductor SC2, and the region directly below the source region S2 in the insulating layer 15. Note that the impurity to be detected hero is boron (¹¹B⁺) with a mass number of 11.

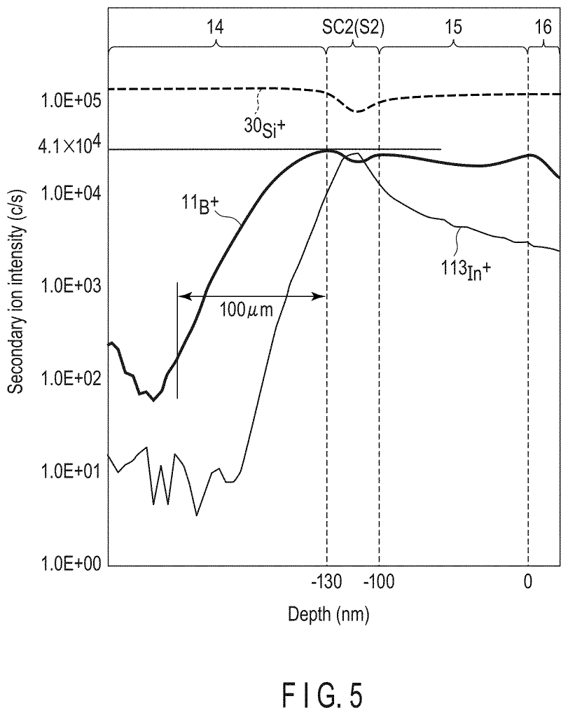

FIG. 5 is a diagram showing the analysis results of the first example. The horizontal axis of the graph indicates the depth (nm) with respect to the interface between the insulating layer 15 and the insulating layer 16, and the vertical axis indicates the secondary ion intensity (counts/sec). The secondary ion intensity is the number of secondary ions detected in one second. The thickness of the insulating layer 14 is about 100 nm, and the thickness of the semiconductor SC2 is about 30 nm. In the figure, analysis results of silicon (³⁰Si⁺) with a mass number of 30 and indium (¹¹³In⁺) with a mass number of 113 are also shown in addition to the impurity (¹¹B⁺) to be detected.

In the first example, the acceleration energy during the ion implantation described with reference to FIG. 3 was set to 29 keV (3*10¹⁵ ions/cm²).

According to the analysis results shown in FIG. 5, it has been confirmed that the impurities contained in the insulating layer 14 are more than those contained in the source region S2. In the distribution of impurities shown in the figure, the peak of the number of impurities was 4.1*10⁴ counts/sec, and it has been confirmed that the peak appears at the interface between the insulating layer 14 and the source region S2. Focusing on the distribution of impurities in the source region S2, the number of impurities at the central portion along the depth direction is less than the number of impurities at the interface with insulating layer 14 and the number of impurities at the interface with insulating layer 15. The number of impurities at the interface between insulating layer 14 and the source region S2 is greater than the number of impurities at the interface between the insulating layer 15 and the source region S2. Focusing on the distribution of impurities in the insulating layer 14, the number of impurities at the interface with the source region S2 is at the maximum, and the number of impurities tends to decrease as it becomes deeper.

In the case where the thickness of the insulating layer 14 is greater than that of the insulating layer 15, the thickness (depth) of impurity distribution in the insulating layer 14 is equal to or greater than the thickness of the insulating layer 15. That is, in the example shown here, the thickness of the insulating layer 15 is 100 nm, and the impurities are distributed in the insulating layer 14 over a depth range of 100 nm or more from the interface with the source region S2.

As to the impurity concentration expressed as the number of impurities per unit volume, the impurity concentration in the insulating layer 14 is higher than that of the source region S2. In the first example, the peak of the impurity concentration can be considered to be at the interface between the insulating layer 14 and the source region S2.

In this first example, a reliability test was carried cut on the transistor TR2. In the reliability test, the ON voltage of the transistor TR2 was continuously applied to the gate electrode GE2, a predetermined voltage was applied between the source and drain, and the initial drain current was compared with the drain current after 10 hours, thus measuring the current drop rate. In the first example, the current drop rate was 2.8%.

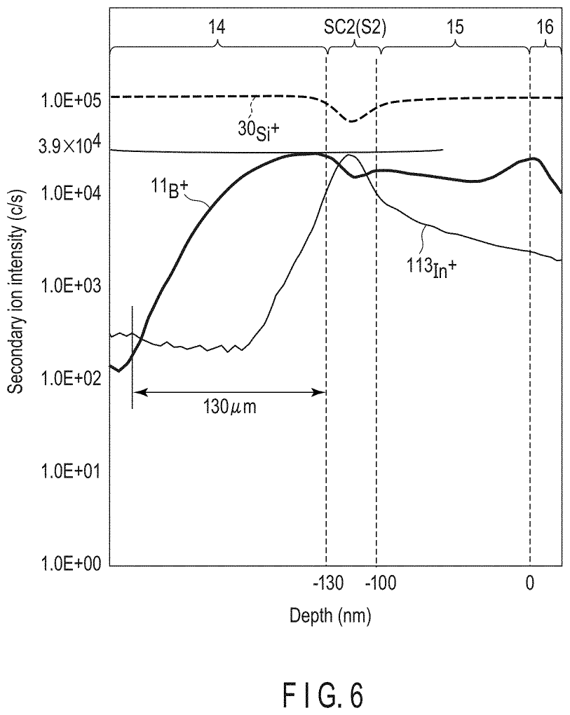

FIG. 6 is a diagram showing analysis results of the second example. The horizontal axis of the figure indicates the depth (nm) with respect to the interface between the insulating layer 15 and the insulating layer 16, and the vertical axis indicates the secondary ion intensity (counts/sec). The thickness of the insulating layer 14 is about 100 nm, and the thickness of the semiconductor SC2 is about 30 nm. In the second example, the acceleration energy during the ion implantation described with reference to FIG. 3 was set to 35 keV (3*10¹⁵ ions/cm²).

According to the analysis results shown in FIG. 6, it has been confirmed that the impurities contained in the insulating layer 14 were more than those contained in the source region S2. In the distribution of impurities shown in the figure, the peak of the number of impurities is 3.9*10⁴ counts/sec, and it has been confirmed that it appears in the insulating layer 14 (especially, near the interface with the source region S2 in the insulating layer 14). Focusing on the distribution of impurities in the source region S2, the number of impurities in the central portion along the depth direction is less than the number of impurities at the interface with the insulating layer 14 and the number of impurities at the interface with the insulating layer 15. The number of impurities at the interface between the insulating layer 14 and the source region S2 is greater than the number of impurities at the interface between the insulating layer 15 and the source region S2. Focusing on the distribution of impurities in the insulating layer 14, the number of impurities in the vicinity of the interface with the source region S2 is at the maximum, and the number of impurities tends to decrease as it becomes deeper.

In the case where the thickness of the insulating layer 14 is greater than that of the insulating layer 15, the thickness (depth) of impurity distribution in the insulating layer 14 has been confirmed to be equal to or greater than the thickness of the insulating layer 15. That is, in the example shown here, the thickness of the insulating layer 15 is 100 nm, and impurities are distributed in the insulating layer 14 over a depth range of 130 nm or more from the interface with the source region S2.

The impurity concentration in the insulating layer 14 is higher than that of the source region S2. In the second example, the peak of the impurity concentration can be considered to be in the insulating layer 14.

In the second example, a similarly, reliability test was carried out on the transistor TR2 as in the first example, and the current drop rate after 10 hours was 1.9%.

In the first and second examples provided above, the analysis was carried out on the region which includes the source region S2 of the semiconductor SC2. Here, in the region which includes the drain region DC of the semiconductor SC2, as well, it is only natural that a similar tendency to that of the region including the source region S2 can also be observed.

As described above, when impurities (e.g., boron) are doped into the semiconductor SC2 which is an oxide semiconductor, by ion implantation, the acceleration energy is optimized, thus increasing the impurities which penetrate the semiconductor SC2 and reach the insulating layer 14, and promoting the formation of crystal defects inside the semiconductor SC2.

When the acceleration energy is thus optimized, the number of impurities in the insulating layer 14 is greater than the number of impurities in the semiconductor SC2, and the peak impurity concentration appears in the insulating layer 14 which is a layer lower than the semiconductor SC2, or at the interface between the semiconductor SC2 and the insulating layer 14.

More crystal defects are created inside the region of the semiconductor SC2, which does not overlap the gate electrode GE2, and thus the source region S2 and the drain region D2, which are low-resistance regions of the semiconductor SC2, are formed. Substantially no impurities reach the inside cf the region overlapping the gate electrode GR2 in the semiconductor SC2, and the channel region C2 which is a high-resistance region, is formed.

As described above, the creation of crystal defects in the source region S2 and the drain region D2 are promoted, and thus the resistance difference between the channel region C2 and the source region S2, and that between the channel region C2 and the drain region D2 increase. Therefore, even after the stress of operating voltage is applied a long period, the degradation of the semiconductor SC2 can be suppressed, and the decrease in current (or increase in resistance) can be suppressed. Thus, it is possible to suppress the degradation of reliability.

As explained above, according to the embodiments, a semiconductor device that can suppress the degradation of reliability can be provided.

Based on the semiconductor device which has been described in the above-described embodiments, a person having ordinary skill in the art may achieve a semiconductor device with an arbitral design change; however, as long as they fall within the scope and spirit of the present invention, such a semiconductor device is encompassed by the scope of the present invention.

A skilled person would conceive various changes and modifications of the present invention within the scope of the technical concept of the invention, and naturally, such changes and modifications are encompassed by the scope of the present invention. For example, if a skilled person adds/deletes/alters a structural element or design to/from/in the above-described embodiments, or adds/deletes/alters a step or a condition to/from/in the above-described embodiment, as long as they fall within the scope and spirit of the present invention, such addition, deletion, and altercation are encompassed by the scope of the present invention.

Furthermore, regarding the present embodiments, any advantage and effect those will be obvious from the description of the specification or arbitrarily conceived by a skilled person are naturally considered achievable by the present invention.

What is claimed is:

1. A semiconductor device comprising:
an insulating substrate;
a first insulating layer disposed above the insulating substrate;
an oxide semiconductor disposed on the first insulating layer;
a second insulating layer which covers the oxide semiconductor; and
a gate electrode disposed on the second insulating layer and overlapping the oxide semiconductor,
the oxide semiconductor including a first region overlapping the gate electrode and a second region not overlapping the gate electrode,
the first insulating layer, the second region and the second insulating layer containing impurities of a same type, and
the impurities contained in a region directly below the second region in the first insulating layer being more than the impurities contained in the second region.

2. The semiconductor device of claim 1, wherein
in distribution of the impurities over the first insulating layer, the second region and the second insulating layer, a peak of the number of impurities is at an interface between the first insulating layer and the second region, or in the first insulating layer.

3. The semiconductor device of claim 1, wherein
a thickness of the first insulating layer is greater than a thickness of the second insulating layer; and
a thickness of a region in which the impurities are distributed in the first insulating layer is equal to or greater than a thickness of the second insulating layer.

4. The semiconductor device of claim 1, wherein
the impurities are boron (B).

5. The semiconductor device of claim 1, wherein
the first insulating layer and the second insulating layer are formed from silicon oxide.
